(19) United States
(12) Patent Application Publication
(10) Pub. No.: US 2026/0148930 A1
(43) Pub. Date: May 28, 2026

(54) METHOD AND APPARATUS FOR ELECTRON BEAM EXPOSURE

(71) Applicant: INSTITUTE OF MICROELECTRONICS, CHINESE ACADEMY OF SCIENCES, Beijing (CN)

(72) Inventors: Yayi Wei, Beijing (CN); Jian Xu, Beijing (CN); Huwen Ding, Beijing (CN); Shang Yang, Beijing (CN)

(21) Appl. No.: 18/995,580

(22) PCT Filed: Sep. 15, 2023
(86) PCT No.: PCT/CN2023/118976

§ 371 Date: Oct. 23, 2025

(30) Foreign Application Priority Data
Jul. 13, 2023 (CN) 202310859215.8

(51) Int. Cl. H01J 37/302; H01J 37/317

(52) U.S. Cl. CPC H01J 37/3026; H01J 37/3174; H01J 2237/31735; H01J 2237/31764

(57) ABSTRACT

A method and apparatus for electron beam exposure. The method comprises: determining one or more to-be-transferred patterns are determined; determining a size of each grid cell in a reference grid are determined based on a size of each to-be-transferred pattern, where each to-be-transferred pattern is aligned with a center of a respective grid cell in the reference grid; and setting a reference rectangle is set, where a relative position is fixed between the reference rectangle and the reference grid. Thereby, the positions of the multiple write fields of the electron beam exposure can be determined, such that each to-be-transferred pattern is disposed at a center of the respective write field. Hence, all to-be-transferred patterns would be exposed at the centers of the respective write fields, thereby optimizing an effect of the exposure.

This application claims priority to Chinese Patent Application No. 202310859215.8, titled “METHOD AND APPARATUS FOR ELECTRON BEAM EXPOSURE”, filed on Jul. 13, 2023, with the China National Intellectual Property Administration, which is incorporated herein by reference in its entirety.

### FIELD

The present disclosure relates to the field of semiconductors, and in particular to a method and apparatus for electron beam exposure.

### BACKGROUND

Photolithography is an important technique for manufacturing semiconductor devices, and develops rapidly along with the semiconductor technology. As a complement for mainstream photolithography means, electron beam lithography is quite different from traditional lithography such as deep-ultraviolet lithography (DUVL) and extreme-ultraviolet lithography (EUVL).

Electron beam lithography is flexible, mask-less, and has ultra-high resolution, and hence has become an indispensable tool for fabricating micro/nano-level structures in research of pilot devices and advanced materials. During electron beam exposure, an electron beam is deflected with respect to an optical axis in a write field under control of an electron lens, such that the electron beam can reach a designated position. The electron beam used in the electron beam lithography is a focused beam with a fixed focal. The larger a deflection angle of the electron beam is subject to during the exposure, the less precise a dimension of a pattern formed by the exposure is.

Therefore, how to improve dimension precision of such patterns is an urgent problem to be solved.

### SUMMARY

An objective of embodiments of the present disclosure is providing a method and an apparatus for electron beam exposure. A to-be-transferred pattern is disposed at a center of a write field of the electron beam exposure, and hence a pattern formed by the exposure is more likely to be precise due to a small offset of to-be-exposed positions in the to-be-transferred pattern. Accordingly, dimensional precision of the formed patterns is improved.

In order to achieve at least the above objective, following technical solutions are provided according to embodiment of the present disclosure.

A method for electron beam exposure is provided according to an embodiment of the present disclosure. The method comprises: determining one or more to-be-transferred patterns; determining a size of each grid cell in a reference grid based on a size of each of the one or more to-be-transferred patterns, where each of the one or more to-be-transferred patterns is aligned with a center of a respective grid cell in the reference grid, and the size of each grid cell is equal to a size of a write field of the electron beam exposure; setting a reference rectangle, where a relative position is fixed between the reference rectangle and the reference grid; and disposing each of the one or more to-be-transferred patterns at a center of a respective write field based on the reference rectangle and the relative position.

In an embodiment, disposing each of the one or more to-be-transferred patterns at the center of the write field based on the reference rectangle and the relative position comprises: disposing grid cells in the reference grid at positions coinciding with write fields, respectively, of the electron beam exposure according to a relative position between an initial write field and the reference grid to dispose each of the one or more to-be-transferred patterns at the center of the respective write field, where a position of the reference rectangle is a position of the initial write field among the write fields of the electron beam exposure, and the relative position between the reference rectangle and the reference grid is the relative position between the initial write field and the reference grid.

In an embodiment, in software for the electron beam exposure, an image layer to which the reference rectangle belongs is identical to an image layer to which the one or more to-be-transferred patterns belong.

In an embodiment, in software for the electron beam exposure, an image layer to which the reference grid belongs is different from an image layer to which the one or more to-be-transferred patterns belong.

In an embodiment, the size of each of the one or more to-be-transferred patterns is smaller than the size of the grid cell.

In an embodiment, the reference rectangle is located at one of four corner grid cells in the reference grid.

In an embodiment, the initial write field coincides with the one of four corner grid cells in the reference grid in position.

In an embodiment, a size of the reference rectangle is equal to the size of the write field of the electron beam exposure.

An apparatus for electron beam exposure is provided according to an embodiment of the present disclosure. The apparatus comprises: a determining unit, configured to determine one or more to-be-transferred patterns and determine a size of each grid cell in a reference grid based on a size of each of the one or more to-be-transferred patterns, where each of the one or more to-be-transferred patterns is aligned with a center of a respective grid cell in the reference grid, and the size of each grid cell is equal to a size of a write field of the electron beam exposure; a first setting unit, configured to set a reference rectangle, where a relative position is fixed between the reference rectangle and the reference grid; and a second setting unit, configured to dispose each of the one or more to-be-transferred patterns at a center of a respective write field based on the reference rectangle and the relative position.

In an embodiment, the second setting unit is configured to dispose grid cells in the reference grid at positions coinciding with write fields, respectively, of the electron beam exposure according to a relative position between an initial write field and the reference grid to dispose each of the one or more to-be-transferred patterns at the center of the respective write field, where a position of the reference rectangle is a position of the initial write field among the write fields of the electron beam exposure, and the relative position between the reference rectangle and the reference grid is the relative position between the initial write field and the reference grid.

Herein the method for electron beam exposure is provided. The method comprises following steps. The one or more to-be-transferred patterns are determined, and the size of each grid cell in the reference grid are determined based on the size of each of the one or more to-be-transferred patterns, where each to-be-transferred pattern is aligned with the center of the respective grid cell in the reference grid. That is, the size of the grid cell depends on the to-be-transferred pattern. Since each grid cell corresponds to a respective write field of the electron beam exposure, the multiple grid cells would form the reference grid which reflects the write fields of the electron beam exposure, and thus the write fields of the electron beam exposure can be determined based on the reference grid. The reference rectangle is set, where the relative position is fixed between the reference rectangle and the reference grid. Thereby, the position of the reference grid can be determined from the position of the reference rectangle, and accordingly the positions of the write fields can be determined. Afterwards, the positions of multiple write fields of the electron beam exposure is determined according to such relative position, such that each to-be-transferred pattern is disposed at the center of the respective write field. Hence, all to-be-transferred patterns would be exposed at the centers of the respective write fields, thereby optimizing an effect of the exposure. It is less likely that dimensions of a pattern formed by the exposure are inaccurate due to an offset of an exposure position of the to-be-transferred pattern. Dimensional precision of the pattern formed by the exposure is improved.

### BRIEF DESCRIPTION OF THE DRAWINGS

Hereinafter drawings to be applied in embodiments of the present disclosure or in conventional technology are briefly described, in order to clarify illustration of technical solutions according to embodiments of the present disclosure or in conventional technology. Apparently, the drawings in the following descriptions are only some embodiments of the present disclosure, and other drawings may be obtained by those skilled in the art based on the provided drawings without exerting creative efforts.

FIG. 1 shows a schematic diagram of a process of electron beam lithography.

FIG. 2 shows a schematic diagram of focusing in electron beam lithography.

FIG. 3 shows a schematic flow diagram of a method for electron beam exposure according to an embodiment of the present disclosure.

FIG. 4 shows a schematic diagram of a to-be-transferred pattern according to an embodiment of the present disclosure.

FIG. 5 shows a schematic diagram of a positional relationship between a to-be-transferred pattern and a write field according to an embodiment of the present disclosure.

FIG. 6 shows a schematic diagram of a reference grid according to an embodiment of the present disclosure.

FIG. 7 shows a schematic diagram of a division of write fields according to an embodiment of the present disclosure.

FIG. 8 shows a schematic diagram of a position of a reference grid according to an embodiment of the present disclosure.

FIG. 9 shows a schematic diagram of a to-be-transferred pattern disposed at a center of a write field according to an embodiment of the present disclosure.

FIG. 10 shows a schematic structural diagram of an apparatus for electron beam exposure according to an embodiment of the present disclosure.

### DETAILED DESCRIPTION OF EMBODIMENTS

Hereinafter specific embodiments of the present disclosure are described in detail below in conjunction with the drawings to clarity and elucidate objectives, features, and advantages of the present disclosure.

Various details are set forth in following description for full understanding of the present disclosure. The present disclosure may be implemented in an embodiment different from those described herein. Those skilled in the art may make deduction without violating a concept of the present disclosure, and hence the present disclosure is not limited to embodiments disclosed as follows.

The present disclosure is described in detail in conjunction with schematic diagrams. In order to facilitate illustrating embodiments, a cross-sectional diagram of a device structure may not be enlarged to scale in all parts, and the schematic diagrams are only exemplary and shall not be construed as limitations on a protection scope of the present disclosure. In practice, a structure shall be manufactured with three spatial dimensions such as a length, a width, and a depth.

Photolithography is an important technique for manufacturing semiconductor devices, and develops rapidly along with the semiconductor technology. As a complement for mainstream photolithography means, electron beam lithography is quite different from traditional lithography such as deep-ultraviolet lithography (DUVL) and extreme-ultraviolet lithography (EUVL).

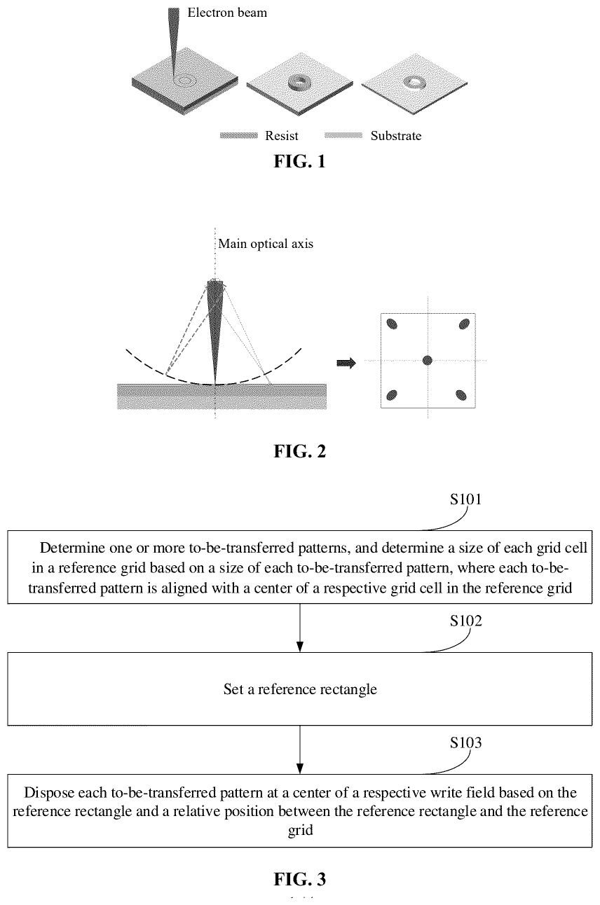

Electron beam lithography is flexible, mask-less, and has ultra-high resolution, and hence has become an indispensable tool for fabricating micro/nano-level structures in research of pilot devices and advanced materials. A process of the electron beam lithography may refer to FIG. 1. A layer of electron-beam resist is deposited on a substrate through spin coating, and the substrate may be a silicon (Si) substrate. The electron-beam resist may be a negative resist. That is, a pattern for the exposure is drawn on the electron-beam resist through an electron beam, and a region of the electron-beam resist irradiated by the electron beam is subject to cross-linking. Hence, such region is substantially sustained in a developer, while a region of the electron-beam resist not irradiated by the electron beam dissolves into the developer, and thus the pattern is eventually formed on the electron-beam resist. Etching techniques may be further applied to transfer the pattern on the electron-beam resist onto the substrate.

Reference is made to FIG. 2. During the electron beam exposure, an electron beam is deflected with respect to an optical axis in a write field under control of an electron lens, such that the electron beam can reach a designated position. The write field refers to a field of exposure, which is formed by a maximum coverage within which the electron beam is allowed to be deflected while a sample stage does not move. The electron beam used in the electron beam lithography is a focused beam with a fixed focal. In FIG. 2, the black dashed line represents a curved plane formed by focusing points of the electron beam. During the exposure, the larger a deflection angle of the electron beam is subject to, or the larger distance the electron beam is deflected by, the larger offset there is from the curved plane, the less precise a dimension of a pattern formed by the exposure is, and the worse imaging quality is. That is, the farther the electron beam deviates from a main optical axis, the larger a degree of defocusing would be. As a result, the electron beam generates a round spot at a center of the write field, while generates an elliptical spot at positions far away from the center of the write field.

Therefore, the to-be-transferred pattern shall be placed as close to the center of the write field as possible, so as to improve dimensional precision of the pattern formed by the exposure. It is urgent to solve the problem regarding how to dispose a to-be-transferred pattern at the center of the write field through software for electron beam exposure, so as to improve the dimensional precision of the pattern formed by the exposure.

Hence, a method for electron beam exposure is provided according to embodiments of the present disclosure. The method comprises following steps. One or more to-be-transferred patterns are determined, and a size of each grid cell in a reference grid are determined based on a size of each of the one or more to-be-transferred patterns, where each to-be-transferred pattern is aligned with a center of a respective grid cell in the reference grid. That is, the size of the grid cell depends on the to-be-transferred pattern. Since each grid cell corresponds to a respective write field of the electron beam exposure, the multiple grid cells would form the reference grid which reflects write fields of the electron beam exposure, and thus the write fields of the electron beam exposure can be determined based on the reference grid. A reference rectangle is set, where a relative position is fixed between the reference rectangle and the reference grid. Thereby, a position of the reference grid can be determined from a position of the reference rectangle, and accordingly positions of the write fields can be determined. Afterwards, the positions of the multiple write fields of the electron beam exposure is determined according to such relative position, such that each to-be-transferred pattern is disposed at the center of the respective write field. Hence, all to-be-transferred patterns would be exposed at the centers of the respective write fields, thereby optimizing an effect of the exposure. It is less likely that dimensions of a pattern formed by the exposure are inaccurate due to an offset of an exposure position of the to-be-transferred pattern. Dimensional precision of the pattern formed by the exposure is improved.

Hereinafter specific embodiments are described in detail in conjunction with the drawings to facilitate understanding technical solutions and technical effects of the present disclosure.

Reference is made to FIG. 3, which is a flow chart of a method for electron beam exposure according to an embodiment of the present disclosure is shown. The method comprises following steps S101 to S103.

In step S101, one or more to-be-transferred patterns are determined, a size of each grid cell in a reference grid is determined based on a size of each to-be-transferred pattern, where each to-be-transferred pattern is aligned with a center of a respective grid cell in the reference grid.

Herein multiple to-be-transferred patterns may be acquired, and a combination of the multiple to-be-transferred patterns serves as a complete pattern for the exposure. The electron beam exposure is performed by using the multiple to-be-transferred patterns, such that the multiple to-be-transferred patterns are transferred onto the electron-beam resist.

Before the electron beam exposure, software for the electron beam exposure needs to perform write-filed assignment for the multiple to-be-transferred patterns, so as to determine a specific location at which each to-be-transferred pattern is placed in the write field.

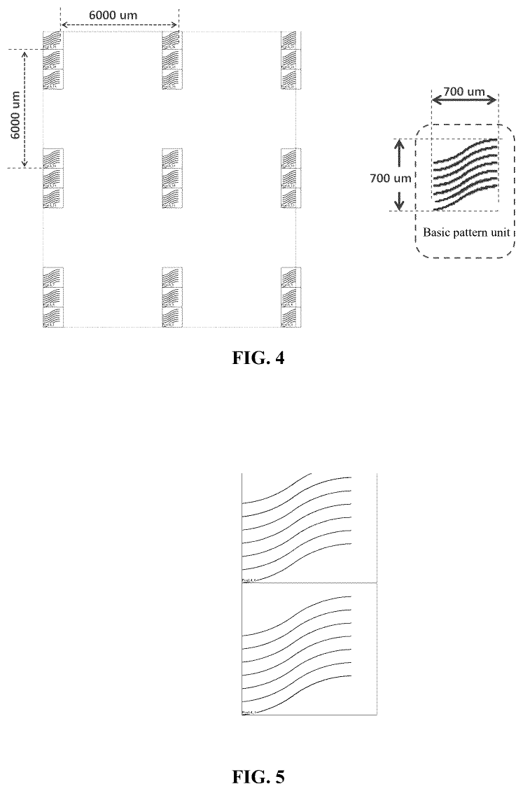

Reference is made to FIG. 4. As an example, nine groups of to-be-transferred patterns are arranged at an interval, and thereby for the complete pattern for exposure. Each group of to-be-transferred patterns comprises three to-be-transferred patterns. Each to-be-transferred pattern may also be called a basic pattern unit. A size of each to-be-transferred pattern may be 700 um×700 um. The complete pattern has a period of 6000 um along the y direction and a period of 6000 um along the x direction. A result of direct write-field delimitation on the multiple to-be-transferred patterns may be as shown in FIG. 5. In FIG. 5, a to-be-transferred pattern is not located at a center of a write field, but at an upper right corner of the write field.

Herein a set of evenly distributed reference grids may serves as a positional reference for the to-be-transferred patterns. The set of reference grids may be predefined and serve as a basis for delimiting a size of the write field. The size of each reference grid is determined based on the size of the to-be-transferred pattern. Thereby, each to-be-transferred pattern can be placed at the center of a respective write field based on the size of the reference grid.

In an embodiment, the sizes of the grid cell in the reference grid may be determined based on the size of each to-be-transferred pattern. Each grid cell corresponds to a respective one of the write fields of the electron beam exposure, and the grid cells constitute the reference grid that reflects the multiple write fields of the electron beam exposure. The size of each grid cell may be equal to the size of the write field of the electron beam exposure. That is, the grid cell and the write field are identical in dimensions, so that the reference grids can serve as the basis for delimiting the write fields. In such case, the to-be-transferred pattern can be disposed at the center of the respective write field, as long as it is disposed at the center of the respective grid cell.

The write fields utilized in the electron beam exposure may be determined based on the grid cell, and the size of the grid cell is determined based on the size of the to-be-transferred pattern. Thereby, the sizes of the write fields are determined based on the sizes of the to-be-transferred patterns.

In an embodiment, the size of each to-be-transferred pattern is smaller than the size of the respective grid cell. Hence, the size of the to-be-transferred pattern is smaller than the size of the respective write field. In such case, the write fields and the to-be-transferred patterns may be in one-to-one correspondence. Errors due to exposure stitching, which refers to that a single to-be-transferred pattern is formed through multiple write fields, are hence avoided.

In practice, the size of the write field of the electron beam exposure may be customized. A maximum size of the write field may be 1000 um×1000 um.

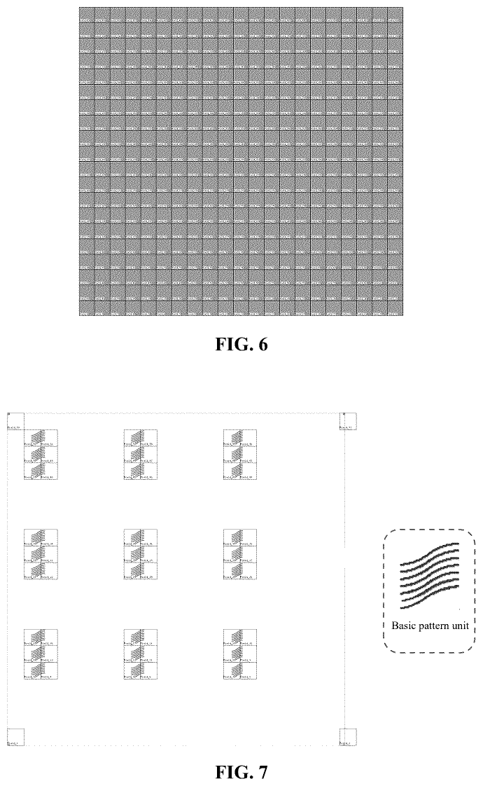

In an embodiment, a size of each to-be-transferred pattern is 700 um×700 um, and the size of the grid cell is determined to be 1000 um×1000 um under the limitation that the size of the to-be-transferred pattern is smaller than the size of the grid cell. The grid cells form a reference grid, reference is made to FIG. 6.

In practice, the reference grid is only configured as a reference for positions of the to-be-transferred pattern(s) and a reference for delimiting the write field(s). The reference grid does not need to be outputted into a file for electron beam exposure file by the software. Therefore, the reference grid and the to-be-transferred pattern may be located in different image layers in the software for electron beam exposure.

In step S102, a reference rectangle is set.

Herein the size of the write field may be determined based on the size of the grid cell of the reference grid. When the software for electron beam exposure performs write-field delimitation, the to-be-transferred pattern is not fully guaranteed to be disposed at the center of the respective grid cell in a case that there lacks a starting point of the delimitation, even if the size of the write field is determined based on the reference grid. That is, the to-be-transferred pattern is not fully guaranteed to be disposed at the center of the respective write field.

Hence, a reference rectangle may be set for the write-field delimitation. The reference rectangle is configured as a basis for delimiting the write fields. A position of the reference rectangle may be fixed, such that the positions of multiple write fields are also fixed.

A relative position between the reference rectangle and the reference grid is fixed, so that the positions of the grid cells can be determined based on the reference rectangle. Thereby, the one-to-one correspondence between the grid cells and the write fields is determined based on the reference rectangle.

The reference rectangle needs to be arranged at an appropriate position. In a case that the position of the reference rectangle is inappropriate, a write field may cut a to-be-transferred pattern after the write field is delimited based on the reference rectangle. For example, a single to-be-transferred pattern may be divided into two write fields, as shown FIG. 7. In such case, there would be errors due to exposure stitching.

In practice, the reference rectangle is configured to delimit the write field(s), and the to-be-transferred pattern(s) are transferred in the exposure according to the delimited write field(s). Hence, the reference rectangle and the to-be-transferred pattern(s) may belong to the same image layer in software for the electron beam exposure.

In step S103, each to-be-transferred pattern is disposed at a center of a respective write field based on the reference rectangle and the relative position.

Herein after determining the reference rectangle and the relative position between the reference rectangle and the reference grid, the positions of multiple write fields of the electron beam exposure may be determined based on the position of the reference rectangle, and the position of each grid cell may be determined based on the relative position. Each to-be-transferred pattern has been placed at the center of the respective grid cell based on the reference grid. The positional relationship between the grid cells and the write fields may be determined through the reference rectangle, such that the to-be-transferred pattern is also disposed at the center of the respective write field during the electron beam exposure. Thereby, each to-be-transferred pattern can be exposed at the center of the respective write field, so as to optimize an effect of the exposure. It is less likely that dimensions of a pattern formed by the exposure are inaccurate due to an offset of an exposure position of the to-be-transferred pattern. Dimensional precision of the pattern formed by the exposure is improved.

In an embodiment, each to-be-transferred pattern may be disposed at the center of the respective grid cell after the size of the grid cell is determined based on the size of the to-be-transferred pattern. Thereby, the subsequent one-to-one correspondence between the grid cells and write fields ensures that the to-be-transferred pattern is disposed at the center of the respective write field.

The position of the reference rectangle may be a position of an initial write field among the multiple write fields of the electron beam exposure. That is, the reference rectangle serves as a reference point of delimiting the write fields. In such case, the relative position between the reference rectangle and the reference grid is a relative position between the initial write field and the reference grid. Then, positions of the grid cells and positions of the write fields of the electron beam exposure coincide respectively based on the relative position between the initial write field and the reference grid. Thereby, the one-to-one correspondence between the positions of the grid cells and the positions of write fields is implemented based on the reference rectangle, and each to-be-transferred pattern can be disposed at the center of the respective write field.

The reference rectangle may be disposed at any of the four corner grid cells in the reference grid. Thereby, the relative position between the reference rectangle and the reference grid is determined, the position of each grid cell can be determined based on the reference rectangle, and a central position of each grid cell can be determined. In a case that the reference rectangle is a corner grid cell of the reference grid, the write fields and the grid cell can match each other when delimiting the write fields based on the reference rectangle, and hence the center positions of the write fields and the center positions of the grid cells can coincide with each other. Thus, the to-be-transferred pattern arranged at the center of the respective grid cell is also disposed at the center of the respective write field.

In a case that the reference rectangle is a corner grid cell of the reference grid, the two-dimensional positions of the write fields can be determined simultaneously when delimiting the write fields. Thus, the positions of the multiple write fields are determined based on a single reference rectangle, and the position of each grid cell in the reference grid is also determined based on the reference rectangle.

The position of the reference rectangle coincides with the position of the initial write field. Therefore, the position of the initial write field may also coincide with the position of any corner grid cell of the four corner grid cells of the reference grid. Thus, the write field division and the reference grid are associated.

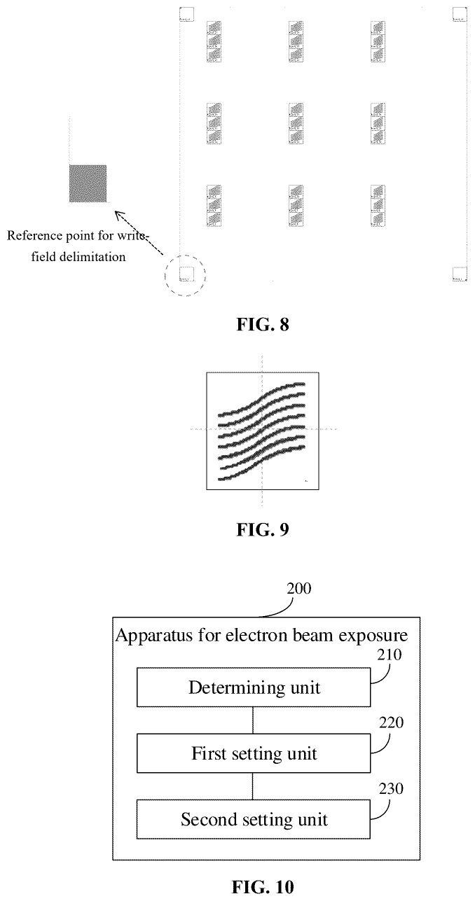

In practice, the software for electron beam exposure start the write-field delimitation from a lower left corner of a region comprising the complete pattern for exposure. That is, the initial write field is located at the lower left corner of such region, as shown in FIG. 8. In such case, the reference rectangle may be disposed at the lower left corner of the region, and a lower left corner grid cell of the reference grid is selected as the reference rectangle. The write-field delimitation starts from a lower left corner of the reference rectangle. Since each to-be-transferred pattern has been placed at the center of the respective grid cell based on the reference grid, it is also at the center of the respective write field due to the positional coincidence between the write fields and the grid cells.

Reference is made to FIG. 8. In an embodiment, the reference rectangle is aligned with the lower left corner grid cell of the reference grid, and the lower left corner point of the reference rectangle coincides with the lower left corner point of the lower left corner grid cell. After delimiting the write field, the to-be-transferred pattern is located in the center of the respective write field, as shown in FIG. 9.

In an embodiment, the size of the reference rectangle may be equal to the size of the write field of the electron beam exposure. Thus, the size of the reference rectangle is also the same as the size of the grid cell, which facilitating delimiting the write fields based on the reference rectangle and determining the position of the reference grid based on the reference rectangle.

Thereby, the reference grid renders the positions of the write fields determined during a designing process of the electron beam exposure, and is capable to assist in positioning the to-be-transferred pattern(s). Mere the reference grid is not enough to control the positions of the write fields, especially the position of the initial write field. The delimitation of write fields in the software of the electron beam exposure may start from the lower left corner of the region comprising the to-be-transferred patterns, and the entire region is gradually and evenly traversed by a step-size equal to the size of the write field. Hence, the position of the reference rectangle may be controlled to determine a starting position of the delimitation, and each to-be-transferred pattern can be disposed at the center of the respective write field based on the positional relationship between the reference rectangle and the reference grid. In addition, the reference grid and reference rectangle, once determined, is applicable to all to-be-transferred patterns. During the electron beam exposure, each to-be-transferred pattern is located at the center of the respective write field, as long as it has been placed at the center of the respective grid cell.

Herein the method for electron beam exposure is provided. The method comprises following steps. The one or more to-be-transferred patterns are determined, and the size of each grid cell in the reference grid are determined based on the size of each of the one or more to-be-transferred patterns, where each to-be-transferred pattern is aligned with the center of the respective grid cell in the reference grid. That is, the size of the grid cell depends on the to-be-transferred pattern. Since each grid cell corresponds to a respective write field of the electron beam exposure, the multiple grid cells would form the reference grid which reflects the write fields of the electron beam exposure, and thus the write fields of the electron beam exposure can be determined based on the reference grid. The reference rectangle is set, where the relative position is fixed between the reference rectangle and the reference grid. Thereby, the position of the reference grid can be determined from the position of the reference rectangle, and accordingly the positions of the write fields can be determined. Afterwards, the positions of multiple write fields of the electron beam exposure is determined according to such relative position, such that each to-be-transferred pattern is disposed at the center of the respective write field. Hence, all to-be-transferred patterns would be exposed at the centers of the respective write fields, thereby optimizing an effect of the exposure. It is less likely that dimensions of a pattern formed by the exposure are inaccurate due to an offset of an exposure position of the to-be-transferred pattern. Dimensional precision of the pattern formed by the exposure is improved.

On a basis of the foregoing method embodiments, an apparatus for electron beam exposure is further provided according to an embodiment of the present disclosure. Reference is made to FIG. 10, which is a schematic structural diagram of an apparatus for electron beam exposure according to an embodiment of the present disclosure. The apparatus 200 for electron beam exposure comprises a determining unit 210, a first setting unit 220, and a second setting unit 230.

The determining unit 210 is configured to determine one or more to-be-transferred patterns and determine a size of each grid cell in a reference grid based on a size of each of the one or more to-be-transferred patterns, where each of the one or more to-be-transferred patterns is aligned with a center of a respective grid cell in the reference grid, and the size of each grid cell is equal to a size of a write field of the electron beam exposure.

The first setting unit 220 is configured to set a reference rectangle, where a relative position is fixed between the reference rectangle and the reference grid.

The second setting unit 230 is configured to dispose each of the one or more to-be-transferred patterns at a center of a respective write field based on the reference rectangle and the relative position.

In an embodiment, the second setting unit 230 is configured to dispose grid cells in the reference grid at positions coinciding with write fields, respectively, of the electron beam exposure according to a relative position between an initial write field and the reference grid to dispose each of the one or more to-be-transferred patterns at the center of the respective write field, where a position of the reference rectangle is a position of the initial write field among the write fields of the electron beam exposure, and the relative position between the reference rectangle and the reference grid is the relative position between the initial write field and the reference grid.

In an embodiment, the reference rectangle and the one or more to-be-transferred patterns belong to a same image layer in software for the electron beam exposure.

In an embodiment, the reference grid and the one or more to-be-transferred patterns are drawn in different image layers in software for the electron beam exposure.

In an embodiment, the size of each of the one or more to-be-transferred patterns is smaller than the size of the grid cell.

In an embodiment, the reference rectangle is located at one of four corner grid cells in the reference grid.

In an embodiment, the position of the initial write field coincides with a position of one of four corner grid cells in the reference grid.

In an embodiment, a size of the reference rectangle is the size of the write field of the electron beam exposure.

The embodiments of the present disclosure are described in a progressive manner, and each embodiment places emphasis on the difference from other embodiments. Therefore, one embodiment can refer to other embodiments for the same or similar parts. Since the apparatuses disclosed in the embodiments correspond to the methods disclosed in the embodiments, the description of the apparatuses is simple, and reference may be made to the relevant part of the methods.

The foregoing embodiments are only preferred embodiments of the present disclosure, and do not limit the present disclosure in any form. The preferred embodiments according to the disclosure are disclosed above, and are not intended to limit the present disclosure. With the method and technical content disclosed above, those skilled in the art can make some variations and improvements to the technical solutions of the present disclosure, or make some equivalent variations on the embodiments without departing from the scope of technical solutions of the present disclosure. All simple modifications, equivalent variations and improvements made based on the technical essence of the present disclosure without departing the content of the technical solutions of the present disclosure fall within the protection scope of the technical solutions of the present disclosure.

1. A method for electron beam exposure, comprising:
determining one or more to-be-transferred patterns;
establishing a reference grid, wherein a size of each grid cell in the reference grid is determined based on a size of each of the one or more to-be-transferred patterns, each of the one or more to-be-transferred patterns is aligned with a center of a respective grid cell in the reference grid, and the size of each grid cell is equal to a unit size of write fields of the electron beam exposure;
determining a position of a reference rectangle, wherein a relative position is fixed between the reference rectangle and the reference grid; and
delimiting the write fields of the electron beam exposure based on the reference rectangle and the relative position to align each of the one or more to-be-transferred patterns at a center of a respective write field of the write fields, where a size of each of the write fields is equal to the unit size.

2. The method according to claim 1, wherein
a position of the reference rectangle is a position of an initial write field among the write fields of the electron beam exposure, and
grid cells of the reference grid coincide with the write fields, respectively, in position after the delimiting.

3. The method according to claim 1, wherein in software for the electron beam exposure, an image layer to which the reference rectangle belongs is identical to an image layer to which the one or more to-be-transferred patterns belong.

4. The method according to claim 1, wherein in software for the electron beam exposure, an image layer to which the reference grid belongs is different from an image layer to which the one or more to-be-transferred patterns belong.

5. The method according to claim 1, wherein the size of each of the one or more to-be-transferred patterns is smaller than the size of the grid cell.

6. The method according to claim 2, wherein the reference rectangle is located at one of four corner grid cells in the reference grid.

7. The method according to claim 6, wherein the initial write field coincides with the one of four corner grid cells in the reference grid in position.

8. The method according to claim 1, wherein a size of the reference rectangle is equal to the size of the write field of the electron beam exposure.

9-10. (canceled)

11. The method according to claim 1, further comprising:
exposing an electron-beam resist under an electron beam based on the delimited write fields and the one or more to-be-transferred patterns to transfer the one or more to-be-transferred patterns onto the electron-beam resist.

12. An apparatus for electron beam exposure, comprising:
a memory storing computer-readable instructions, and
a processor, wherein the computer-readable instructions when executed by the processor configure the apparatus to:
determine one or more to-be-transferred patterns;
establish a reference grid, wherein a size of each grid cell in the reference grid is determined based on a size of each of the one or more to-be-transferred patterns, each of the one or more to-be-transferred patterns is aligned with a center of a respective grid cell in the reference grid, and the size of each grid cell is equal to a unit size of write fields of the electron beam exposure;
determine a position of a reference rectangle, wherein a relative position is fixed between the reference rectangle and the reference grid; and
delimit the write fields of the electron beam exposure based on the reference rectangle and the relative position to align each of the one or more to-be-transferred patterns at a center of a respective write field of the write fields, where a size of each of the write fields is equal to the unit size.

13. A non-transitory computer-readable storage medium, storing computer-readable instructions, wherein the computer-readable instructions when executed by a processor configured a device to:
determine one or more to-be-transferred patterns;
establish a reference grid, wherein a size of each grid cell in the reference grid is determined based on a size of each of the one or more to-be-transferred patterns, each of the one or more to-be-transferred patterns is aligned with a center of a respective grid cell in the reference grid, and the size of each grid cell is equal to a unit size of write fields of the electron beam exposure;
determine a position of a reference rectangle, wherein a relative position is fixed between the reference rectangle and the reference grid; and
delimit the write fields of the electron beam exposure based on the reference rectangle and the relative position to align each of the one or more to-be-transferred patterns at a center of a respective write field of the write fields, where a size of each of the write fields is equal to the unit size.
